(19) United States
(12) Patent Application Publication
(10) Pub. No.: US 2020/0303667 A1
(43) Pub. Date: Sep. 24, 2020

(54) ENHANCING THE LIFETIME OF ORGANIC SALT PHOTOVOLTAICS

(71) Applicant: Board of Trustees of Michigan State University, East Lansing, MI (US)

(72) Inventors: Richard R. LUNT, Williamston, MI (US); Christopher TRAVERSE, Haslett, MI (US)

(73) Assignee: Board of Trustees of Michigan State University, East Lansing, MI (US)

(21) Appl. No.: 16/765,625

(22) PCT Filed: Dec. 5, 2018
(86) PCT No.: PCT/US2018/064010

§ 371 Date: May 20, 2020

Related U.S. Application Data
(60) Provisional application No. 62/594,839, filed on Dec. 5, 2017.

(51) Int. Cl. H01L 51/44; H01L 51/00

(52) U.S. Cl. CPC H01L 51/448; H01L 51/0046; H01L 51/0064; H01L 51/005

(57) ABSTRACT

An organic photovoltaic device is provided. The organic photovoltaic device includes an active layer having an organic photoactive component having a water contact angle of greater than or equal to about 65°. Methods of making the organic photovoltaic device are also provided.

### CROSS-REFERENCE TO RELATED APPLICATIONS

This application claims the benefit of U.S. Provisional Application No. 62/594,839, filed on Dec. 5, 2017. The entire disclosure of the above application is incorporated herein by reference.

### GOVERNMENT RIGHTS

This invention was made with government support under 1254662 and 1511098 awarded by the National Science Foundation and under GU0115873 awarded by the U.S. Department of Education. The government has certain rights in the invention.

### FIELD

The present disclosure relates to enhancing the lifetime of organic and organic salt photovoltaics.

### BACKGROUND

This section provides background information related to the present disclosure which is not necessarily prior art.

Highly transparent photovoltaics (HTPVs) can enable new routes to solar deployment on building windows, automobiles, electronic displays, and virtually any other surface without aesthetic compromise. While high device performance and visible transmission are critical for many of these new commercial deployment routes, application-specific lifetime is equally important because it largely determines installation feasibility and total power output. Although the longest achievable lifetimes remain one of the major goals of PV research, it is also important in practical distribution to match technologies to their precise applications. Understanding the effects of molecular structure and composition on the stability of wavelength selective photoactive materials is therefore key to enabling wide-scale HTPV deployment.

HTPVs have incorporated NIR-selective organic small molecules, polymers, and molecular salts as donor materials. While a large range of small molecules and polymers have been developed for many years, NIR-selective molecular salts have only recently been investigated in earnest for organic photovoltaic (OPV) devices. It has been shown that exchanging the anion shifts the frontier orbital energies, and thus, the highest occupied molecular orbital (HOMO) and lowest unoccupied molecular orbital (LUMO) of the collective salt, without significantly affecting absorption or bandgap. This can enable the rapid optimization of the interface gap (donor HOMO and acceptor LUMO offset) and open circuit voltage (V_{oc}) with virtually any given acceptor. Physical properties such as solubility and surface energies can similarly be tailored with various anions. Optical absorption can then be tuned independently via conjugation of the cation, which has allowed efficient NIR photoresponse as deep as 1600 nm.

Molecular and organic semiconductors utilized to fabricate HTPVs are often considered to have inherently low stability compared to inorganic technologies due to a tendency to react with oxygen and moisture. However, encapsulation alone can alleviate many of the stability issues with OPVs and organic light emitting diodes, so that devices retain high performance for many years. Recent organic demonstrations with reported extrapolated device lifetimes of greater than 20 years provide a clear indication that OPV technologies can be just as viable for long-term applications as inorganic technologies, even though most reports demonstrate extrapolated and non-extrapolated lifetimes of about 2 years and less than 1.5 years, respectively.

Although the properties of photoactive layers, transport layers, and electrodes, have previously been correlated to OPV lifetime, little work has focused explicitly on NIR wavelength selective photoactive materials with bandgaps applicable to HTPVs. Accordingly, there remains a need to develop methods for extending lifetimes of photovoltaic devices and to develop photovoltaic devices having extended lifetimes.

### SUMMARY

This section provides a general summary of the disclosure, and is not a comprehensive disclosure of its full scope or all of its features.

In various aspects, the current technology provides an organic photovoltaic device including an active layer having an organic photoactive component having a water contact angle of greater than or equal to about 65°.

In one aspect, the organic photoactive component is a neutral organic molecule.

In one aspect, the organic photoactive component is an organic salt including an ion and a counterion.

In one aspect, the organic salt includes a counterion of fluorinated phenyl borate.

In one aspect, the organic salt includes a counterion ion of tetrakis(pentafluorophenyl)borate and the organic photovoltaic device has a lifetime greater than or equal to about 5 years.

In one aspect, the organic salt includes an absolute highest occupied molecular orbital energy of greater than or equal to about 5.2 eV.

In one aspect, the organic photoactive component has a water contact angle of greater than or equal to about 90°.

In various aspects, the current technology also provides a method of fabricating a photovoltaic device. The method includes selecting an organic photoactive component, measuring a water contact angle of the organic photoactive component, determining whether the organic photoactive component has a water contact angle of greater than or equal to about 65°, when the water contact angle is less than about 65%, tuning the organic photoactive component until the organic photoactive component has a water contact angle that is greater than or equal to about 65°, and disposing the organic photoactive component having a water contact angle of greater than or equal to about 65° into a photovoltaic device.

In one aspect, the organic photoactive component is a neutral organic molecule or an organic salt including an ion and a counterion.

In one aspect, the tuning the organic photoactive component until the organic photoactive component has a water contact angle that is greater than or equal to about 65° includes adding at least one hydrophobic moiety to the neutral organic molecule or to the counterion.

In one aspect, the at least one hydrophobic moiety is selected from the group including CH₃, —SH, —Cl, —F, —CCl₃, PhCl₆, -PhCl₅, —CF₃, PhF₆, -PhF₆, -PhF_{X}Cl_{y} (X=1 to 5 and Y=5−X), and combinations thereof.

In one aspect, the counterion is a fluorocarbon or a fluorinated phenyl borate.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a schematic illustration of a first device according to various aspect of the present technology.

FIG. 1B is a schematic illustration of a second device according to various aspects of the present technology.

FIG. 1C is a schematic illustration of a third device according to various aspects of the present technology.

FIG. 2A shows the molecular structures for the heptamethine (Cy⁺) cation (top) and the anions paired with it: (1) TPFB⁻, (2) TRIS⁻, (3) TFM⁻, (4) PF₆⁻, and (5) I⁻.

FIG. 2B is the molecular structure for ClAlPc.

FIG. 2C shows the normalized extinction coefficients for each donor.

FIGS. 3A-3C are representative ClAlPc PHJ devices held at short circuit (FIG. 3A), open circuit (FIG. 3B), and maximum power point (MPP) (FIG. 3C). A significant difference in stability across these three loading conditions for any architecture is not observed.

FIGS. 4A-4D show normalized lifetime data for ClAlPc PHJ and PMHJ devices. J_{sc}, V_{oc}, FF, and PCE are shown in FIG. 4A, FIG. 4B, FIG. 4C, and FIG. 4D, respectively. Representative error bars denote the maximum standard deviations across all devices for each performance parameter.

FIGS. 5A-5D show normalized lifetime data for CyTPFB, CyTRIS, CyPF₆, CyI, and CyTFM devices. J_{sc}, V_{oc}, FF, and PCE are shown in FIG. 5A, FIG. 5B, FIG. 5C, and FIG. 5D respectively. Representative error bars denote maximum standard deviations across all devices for each performance parameter.

FIGS. 6A-6B show champion PCE lifetime data for all ClAlPc (FIG. 6A) and molecular salt (FIG. 6B) architectures from FIGS. 4A-4D and FIGS. 5A-5D.

FIGS. 7A-7D show normalized EQE data measured from representative ClAlPc PHJ (FIG. 7A), ClAlPc PMHJ (FIG. 7B), CyPF₆ (FIG. 7C), and CyTPFB (FIG. 7D) devices during lifetime testing.

FIGS. 8A-8C are transmission spectra for CyTPFB (FIG. 8A), ClAlPc (PHJ) (FIG. 8B), and ClAlPc (PMHJ) (FIG. 8C) devices without top Ag electrodes measured before and after illumination.

FIGS. 9A-9F are representative photographs of water droplets on 50 nm films of CyTPFB (FIG. 9A), CyTRIS (FIG. 9B), ClAlPc:C₆₀ (FIG. 9C), CyI (FIG. 9D), ClAlPc (FIG. 9E), and CyTFM (FIG. 9F), shown in order of decreasing hydrophobicity, from which contact angles were measured.

FIGS. 10A-10B are AFM images collected on CyTPFB (FIG. 10A) and CyTFM (FIG. 10B) films deposited from 12 mg/ml solutions over Si. The RMS roughnesses are 0.36±0.04 nm and 0.27±0.01 nm, respectively.

FIG. 11 shows champion lifetimes (T₅₀) plotted as a function of isolated donor film water contact angle for all devices. Lifetime is directly correlated to water contact angle for both vacuum deposited small molecule donor and solution deposited molecular salt devices.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges. As referred to herein, ranges are, unless specified otherwise, inclusive of endpoints and include disclosure of all distinct values and further divided ranges within the entire range. Thus, for example, a range of “from A to B” or “from about A to about B” is inclusive of A and B.

Example embodiments will now be described more fully with reference to the accompanying drawings.

The current technology relates to organic chemistry, organic semiconductors, and organic photovoltaics. The photovoltaic devices and light harvesting systems can be opaque, transparent, heterojunction cells, or multi-junction cells. The devices and systems include at least one of neutral organic molecules and organic salts that selectively or predominately harvest light with wavelengths in the infrared (IR) region of the solar spectrum, near IR (NIR) region of the solar spectrum, or both the IR and NIR regions of the solar spectrum.

More particularly, the current technology provides a molecular design strategy for improving the stability of near-infrared absorbers for long-lifetime organic and transparent photovoltaics. Tailoring or tuning an absorber to maximize thin-film hydrophobicity yields significant improvements in device lifetime. For organic salts, hydrophobicity is determined largely by a counterion (e.g., a non-photoactive anion or cation) or a photoactive ion (i.e., a photoactive cation or anion), which can enhance device lifetimes by several orders of magnitude with decoupled dependence on orbital energy levels or optical absorption. As used herein, the term “lifetime” refers to the time over which a power conversion efficiency (PCE) of a device reaches either 80% or 50% of an initial value for the device after any burn-in (T₈₀ or T₅₀, respectively).

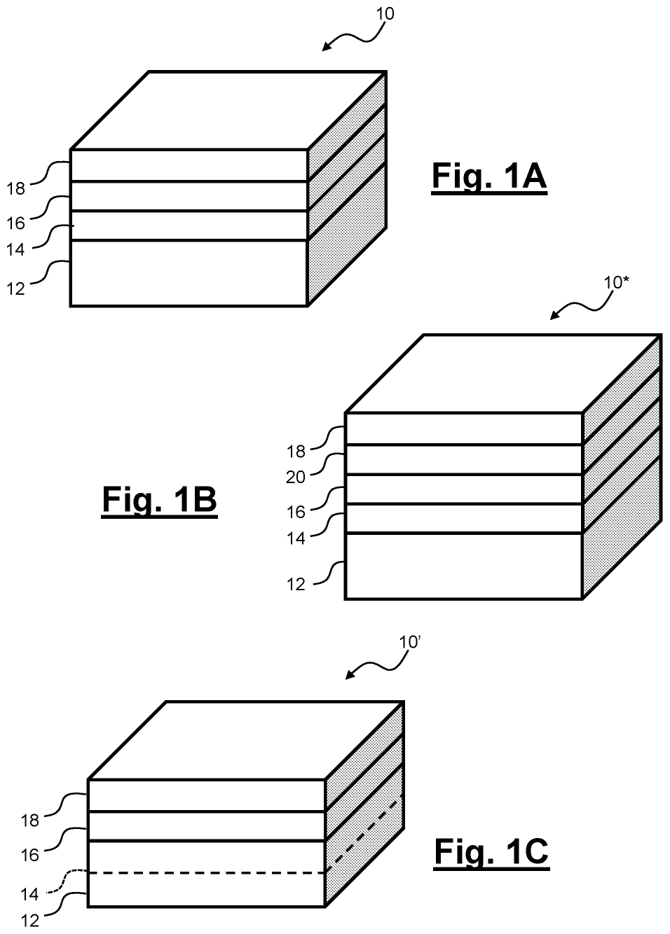

With reference to FIG. 1A, the present technology provides an organic photovoltaic device 10. The photovoltaic device 10 comprises a substrate 12, a first electrode 14, an active layer 16 comprising an organic photoactive component (i.e., an electron donor), and a second electrode 18. In some embodiments, the organic photovoltaic device 10 also includes at least one complementary layer comprising an electron acceptor. The complementary layer can be included in the active layer 16 or provided as a separate distinct complementary layer 20, as shown with another device 10* in FIG. 1B. Therefore, the active layer 16 can comprise, consist essentially of, or consist of the organic photoactive component and the electron acceptor (FIG. 1A), or the active layer 16 can comprise, consist essentially of, or consist of the organic photoactive component and the electron acceptor is provided in a complementary layer 20 (FIG. 1B). Here, the term “consists essentially of” means that a layer can only include trace amounts, i.e., less than or equal to about 10 wt. %, of additional unavoidable impurity materials that do not substantially affect the activity (i.e., by less than about 10%) generated by the pairing of the electron donor (photoactive component) and electron acceptor.

In various embodiments, the photovoltaic device 10, 10* includes at least one, or a plurality of, active layers 16, at least one, or a plurality of, complementary layers 20 that include electron acceptors, or at least one of, or a plurality of, both active layers 16 and complementary layers 20. The active layer 16 and any complementary layers 20 have a thickness of from about 1 nm to about 300 nm, or from about 3 nm to about 100 nm. Although not shown, in some embodiments the photovoltaic device 10, 10* also includes buffer layers positioned between any of the layers and electrodes 12, 14, 16, 18, 20 which may block excitons, modify a work function or collection barrier, induce ordering or templating, or serve as optical spacers. The photovoltaic device 10, 10* has an open circuit voltage that is within about 30% or about 20% of the excitonic limit as defined in Lunt et al., “Practical Roadmap and Limits to Nanostructured Photovoltaics” (Perspective) Adv. Mat. 23, 5712-5727, 2011, which is incorporated herein by reference in its entirety. Briefly, the form for the excitonic limiting open circuit voltage, i.e., the excitonic limit, under 1 Sun follows roughly 80% of the theoretical Shockley-Queisser thermodynamically limited open circuit voltage that is limited by the smallest of the band gaps. The factor of 80% in the excitonic limit accounts for the minimum energetic driving force required to dissociate excitons. Alternatively, the photovoltaic device 10, 10* has an open circuit voltage that is within about 50% or about 35% of the thermodynamic limit.

The substrate 12 of the photovoltaic device 10, 10* can be any visibly transparent or visibly opaque material 12 known in the art. Non-limiting examples of transparent substrates include glass, low iron glass, plastic, poly(methyl methacrylate) (PMMA), poly-(ethylmethacrylate) (PEMA), (poly)-butyl methacrylate-co-methyl methacrylate (PBMMA), polyethylene terephthalate (PET), and polyimides, such as Kapton® polyimide films (DuPont, Wilmington, Del.). Non-limiting examples of opaque substrates include amorphous silicon, crystalline silicon, halide perovskites, stainless steel, metals, metal foils, and gallium arsenide.

The substrate 12 comprises the first electrode 14. As shown in FIGS. 1A and 1B, the first electrode 14 is positioned or deposited on a first surface of the substrate 12 as, for example, a thin film, by solution deposition, drop casting, spin-coating, doctor blading, vacuum deposition, plasma sputtering, or e-beam deposition, as non-limiting examples, with thicknesses that allow for active-layer films that are visibly transparent or visibly opaque. However, in various embodiments, multiple electrodes 14 may be present, such as with a device having a first electrode on a first surface of a substrate and on a second opposing surface of the substrate (not shown). In another embodiment, depicted as FIG. 1C, a photovoltaic device 10′ has the same components as the photovoltaic device 10 of FIG. 1A (a substrate 12, an electrode 14, and an active layer 16, and optionally buffer layers); however, the first electrode 14 is positioned within the substrate 12. Therefore, the substrate 12 may include materials that act as the electrode 14, such that the substrate 12 and electrode 14 are visibly indistinguishable. Although not shown, the device 10′ can also include at least one of a complementary layer 20 including an electron acceptor and a buffer layer. In any embodiment, the first electrode 14 can be composed of any material known in the art. Non-limiting examples of electrode materials include indium tin oxide (ITO), aluminum doped zinc oxide (AZO), indium zinc oxide, zinc oxide, and gallium zinc oxide (GZO), ultra-thin metals, such as Ag, Au, and Al, graphene, graphene oxide, poly(3,4-ethylenedioxythiophene) polystyrene sulfonate (PEDOT:PSS), MoO₃, tris-(8-hydroxyquinoline)aluminum (Alq₃), and combinations thereof. In various embodiments, the first electrode 14 has a thickness of from about 1 nm to about 500 nm, from about 1 nm to about 200 nm, from about 10 nm to about 200 nm, from about 15 nm to about 150 nm, or from about 500 nm or less. Notwithstanding, it is understood that changing the thickness of the first electrode 14 may alter the visible transparency of the photovoltaic device 10, 10*, 10′ via modulation of complex interference associated with the multiple layers 12, 14, 16 in the photovoltaic device 10, 10*, 10′.

The active layer 16 is positioned or disposed on a surface of the electrode 14 in the photovoltaic device 10, 10*, 10′, such as by solution deposition, drop casting, spin-coating, doctor blading, or vacuum deposition, as non-limiting examples, with thicknesses that allow for films that are visibly transparent or visibly opaque. Therefore, the photovoltaic device 10 includes the first electrode 14, which has a first surface in contact with the substrate 12 and a second surface in direct contact with active layer 16. However, in some embodiments, at least one buffer layer or at least one passive layer is positioned between the substrate 12 and the first electrode 14 and/or at least one buffer layer or at least one passive layer is positioned between the first electrode 14 and the active layer 16. Also, the second electrode 18 may be in direct contact with the active layer 16 or a buffer layer may be positioned between the second electrode 18 and the active layer 16. In some embodiments, such as with the photovoltaic device 10′ of FIG. 1C, the first electrode 14 is positioned within the substrate 12. In such embodiments, the active layer 16 is positioned on, and is in direct contact with, a first surface of the substrate 12.

As mentioned above, the active layer 16 comprises an organic photoactive (electron donor) component. The organic photoactive component is at least one of a neutral organic molecule and an organic salt comprising an ion and a counterion. As understood by a person having ordinary skill in the art when the ion is a cation, the counterion is an anion; and when the ion is an anion, the counterion is a cation. In various embodiments, the photoactive component acts as an electron donor and is paired with electron acceptors in the active layer 16 The electron acceptors are fullerenes, non-fullerenes, or a combination thereof. Non-limiting examples of fullerene electron acceptors include C₂₀ fullerene, C₂₄ fullerene, C₂₆ fullerene, C₂₈ fullerene, C₃₀ fullerene, C₃₂ fullerene, C₃₄ fullerene, C₃₆ fullerene, C₃₈ fullerene, C₄₀ fullerene, C₄₂ fullerene, C₄₄ fullerene, C₄₆ fullerene, C₄₈ fullerene, C₅₀ fullerene, C₅₂ fullerene, C₆₀ fullerene, C₇₀ fullerene, C₇₂ fullerene, C₇₄ fullerene, C₇₆ fullerene, C₇₈ fullerene, C₈₀ fullerene, C₈₂ fullerene, C₈₄ fullerene, C₈₆ fullerene, C_{go} fullerene, C₉₂ fullerene, C₉₄ fullerene, C₉₆ fullerene, C₉₈ fullerene, C₁₀₀ fullerene, C₁₈₀ fullerene, C₂₄₀ fullerene, C₂₆₀ fullerene, C₃₂₀ fullerene, C₅₀₀ fullerene, C₅₄₀ fullerene, C₇₂₀ fullerene, [6,6]-phenyl C₆₁ butyric acid methyl ester (PC₆₁ BM), bis(1-[3-(methoxycarbonyl) propyl]-1-phenyl)-[6.6]C₆₂ (Bis PC₆₂BM), indene C₆₀ mono adduct (C₆₀—ICMA), indene C₆₀ bis adduct (C₆₀—ICBA), indene C₆₀ tris adduct (C₆₀—ICTA), C₆₀-(N,N-dimethyl pyrrolidinium iodide) adduct (WSC₆₀PI), C₆₀-(N,N-dimethyl pyrrolidinium ammonium)n adduct (WSC₆₀PS), C₆₀-(malonic acid)n (WSC₆₀MA), C₆₀(OH)n with n=30-50 (fullerol C₆₀), [6,6]-phenyl C₇₁ butyric acid methyl ester (PC₇₁ BM), bis(1-[3-(methoxycarbonyl) propyl]-1-phenyl)-[6.6]C₇₂ (Bis PC₇₂BM), indene C₇₀ mono adduct (C₇₀—ICMA), indene C₇₀ bis adduct (C₇₀-ICBA), indene C₇₀ tris adduct (C₇₀—ICTA), C₇₀-(N,N-dimethyl pyrrolidinium iodide) adduct (WSC₇₀PI), C₇₀-(N,N-dimethyl pyrrolidinium ammonium)n adduct (WSC₇₀PS), C₇₀-(malonic acid)n (WSC₇₀MA), C₇₀(OH)n with n=30-50 (fullerol C₇₀), and combinations thereof. Non-limiting examples of non-fullerene electron acceptors include perylene diimides (PDI)-based non-fullerenes, diketopyrrolopyrrole (DPP)-based non-fullerenes, indacenodithiophene (IDT)-based non-fullerenes, and indacenodithienol[3,2-b] thipene (IDTT)-based non-fullerenes, and combinations thereof. Non-limiting specific examples of non-fullerenes include 3,9-bis(2-methylene-(3-(1,1-dicyanomethylene)-indanone))-5,5,11,11-tetrakis(4-hexylphenyl)-dithieno[2,3-d:2′,3′-d′]s-indaceno[1,2-b:5,6-b′]dithiophene (ITIC), 3,9-bis(2-methylene-(3-(1,1-dicyanomethylene)-5,6-difluoroindanone))-5,5,11,11-tetrakis(4-hexylphenyl)-dithieno[2,3-d:2′,3′-d′]s-indaceno[1,2-b:5,6-b′]dithiopene (ITIC-4F, fluoro ITIC), IEICO (2055812-53-6), IEICO-4F (CAS No. 2089044-02-8), and combinations thereof.

For opaque (non-transparent) devices 10, the organic photoactive component harvests (absorbs) light having any wavelength, i.e., at least one of UV, VIS, NIR, and IR light. For visibly transparent devices 10, the organic photoactive component harvests (absorbs) light with strongest peak wavelengths in the NIR, or IR regions of the solar spectrum, or both the NIR and IR regions. As used herein, “UV” light has a wavelength of greater than or equal to about 10 nm to less than about 400 nm, “VIS” light has a wavelength of greater than or equal to about 400 nm to less than or equal to about 675 nm, “NIR” light has a wavelength of greater than about 675 nm to less than or equal to about 1500 nm, and “IR” light has a wavelength of greater than about 1500 nm to less than or equal to about 1 mm. In embodiments where the device 10, 10*, 10′ is visibly transparent, the organic photoactive component has a strongest peak absorbance of greater than or equal to about 675 nm, where less than or equal to about 20% or less than or equal to about 10% of the total light contacting the organic photoactive component is absorbed by the organic photoactive component. Put another way, in visibly transparent devices 10, the organic photoactive component absorbs light such that less than or equal to about 20% or less than or equal to about 10% of the total light absorbed by the photoactive component has a wavelength of less than about 675 nm. Also, as used herein the terms “transparent” or “visibly transparent” refer to devices that have an average visible transparency, weighted by the photopic response of an eye, of greater than or equal to about 45%, greater than or equal to about 60%, greater than or equal to about 75%, greater than or equal to about 90% or more for specular transmission. The terms “opaque” or “visibly opaque” refer to devices that have an average visible transparency, weighted by the photopic response of an eye of 10% or less for specular transmission. Devices that have an average visible transparency, weighted by the photopic response of an eye of between 10% to 45% for specular transmission are “semitransparent.”

In various embodiments, the photoactive neutral organic molecule is a cyanine, phthalocyanine, a porphyrin, a thiophene, a perylene, a polymer, derivatives thereof, and combinations thereof, as non-limiting examples. For example, a phthalocyanine can include copper phthalocyanine, and chloroaluminum phthalocyanine (ClAlPc).

In various embodiments, the photoactive organic salt is a polymethine salt, cyanine salt, derivative thereof, or combination thereof, as non-limiting examples. Non-limiting examples of suitable organic ions (which are “base ions” relative to their derivatives) that form organic salts in the presence of a counterion include 1-Butyl-2-(2-[3-[2-(1-butyl-1H-benzo[cd]indol-2-ylidene)-ethylidene]-2-phenyl-cyclopent-1-enyl]-vinyl)-benzo[cd]indolium (peak absorbance at 1024 nm), 1-Butyl-2-(2-[3-[2-(1-butyl-1H-benzo[cd]indol-2-ylidene)-ethylidene]-2-chloro-cyclohex-1-enyl]-vinyl)-benzo[cd]indolium (peak absorbance at 1014 nm), 1-Butyl-2-(2-[3-[2-(1-butyl-1H-benzo[cd]indol-2-ylidene)-ethylidene]-2-phenyl-cyclohex-1-enyl]-vinyl)-benzo[cd]indolium (peak absorbance at 997 nm), 1-Butyl-2-(2-[3-[2-(1-butyl-1H-benzo[cd]indol-2-ylidene)-ethylidene]-2-diphenylamino-cyclopent-1-enyl]-vinyl)-benzo[cd]indolium (peak absorbance at 996 nm), 1-Butyl-2-[7-(1-butyl-1H-benzo[cd]indol-2-ylidene)-hepta-1,3,5-trienyl]-benzo[cd]indolium (peak absorbance at 973 nm), 2-[2-[2-chloro-3-[2-(1,3-dihydro-3,3-dimethyl-1-ethyl-2H-benz[e]indol-2-ylidene)ethylidene]-1-cylohexen-1-yl]-ethenyl]-3,3-dimethyl-1-ethyl-1H-benz[e]indolium (“Cy+”; peak absorbance at 820 nm), N,N,N′,N′-Tetrakis-(p-di-n-butylaminophenyl)-p-benzochinon-bis-immonium (peak absorbance at 1065 nm), 4-[2-[2-Chloro-3-[(2,6-diphenyl-4H-thiopyran-4-ylidene)ethylidene]-1-cyclohexen-1-yl]ethenyl]-2,6-diphenylthiopyrylium, 1-Butyl-2-[2-[3-[(1-butyl-6-chlorobenz[cd]indol-2(1H)-ylidene)ethylidene]-2-chloro-5-methyl-1-cyclohexen-1-yl]ethenyl]-6-chlorobenz[cd]indolium, 1-Butyl-2-[2-[3-[(1-butyl-6-chlorobenz[cd]indol-2(1H)-ylidene)ethylidene]-2-chloro-1-cyclohexen-1-yl]ethenyl]-6-chlorobenz[cd]indolium, Dimethyl{4-[1,7,7-tris(4-dimethylaminophenyl)-2,4,6-heptatrienylidene]-2,5-cyclohexadien-1-ylidene}ammonium, 5,5′-Dichloro-11-diphenylamino-3,3′-diethyl-10,12-ethylenethiatricarbocyanine, 2-[2-[2-Chloro-3-[2-(1,3-dihydro-1,1,3-trimethyl-2H-benzo[e]-indol-2-ylidene)-ethylidene]-1-cyclohexen-1-yl]-ethenyl]-1,1,3-trimethyl-1H-benzo[e]indolium, 2-[2-[2-Chloro-3-[2-(1,3-dihydro-1,3,3-trimethyl-2H-indol-2-ylidene)-ethylidene]-1-cyclopenten-1-yl]-ethenyl]-1,3,3-trimethyl-3H-indolium, 2-[2-[3-[(1,3-Dihydro-3,3-dimethyl-1-propyl-2H-indol-2-ylidene)ethylidene]-2-(phenylthio)-1-cyclohexen-1-yl]ethenyl]-3,3-dimethyl-1-propylindolium, 1,1′,3,3,3′,3′-4,4′,5,5′-di-benzo-2,2′-indotricarbocyanine perchlorate, 2-[2-[2-Chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium, 3,3′-Diethylthiatricarbocyanine, 2-[[2-[2-[4-(dimethylamino)phenyl]ethenyl]-6-methyl-4H-pyran-4-ylidene]methyl]-3-ethyl, 2-[7-(1,3-Dihydro-1,3,3-trimethyl-2H-indol-2-ylidene)-1,3,5-heptatrienyl]-1,3,3-trimethyl-3H-indolium, cyanine3 (Cy3), cyanine3.5 (Cy3.5), cyanine5 (Cy5), cyanine5.5 (Cy5.5), cyanine7 (Cy7), cyanine7.5 (Cy7.5), derivatives thereof, and combinations thereof. As used herein, “derivatives” of the organic ions refer to or include organic ions that resemble a base organic ion, but that contain minor changes, variations, or substitutions, such as in, for example, solubilizing groups with varying alkyl chain length or substitution with other solubilizing groups, which do not substantially change the bandgap or electronic properties, as well as substitutions at a central methane position (X,Y) with various halides or ligands.

Non-limiting examples of counterions (which are “base counterions” relative to their derivatives) that form salts with the organic ions include halides, such as F—, Cl—, I—, and Br—; aryl borates, such as tetraphenylborate, tetra(p-tolyl)borate, tetrakis(4-biphenylyl)borate, tetrakis(1-imidazolyl)borate, tetrakis(2-thienyl)borate, tetrakis(4-chlorophenyl)borate, tetrakis(4-fluorophenyl)borate, tetrakis(4-tert-butylphenyl)borate, tetrakis(pentafluorophenyl)borate (TPFB), tetrakis[3,5-bis(trifluoromethyl)phenyl]borate (TFM), [4-[bis(2,4,6-trimethylphenyl)phosphino]-2,3,5,6-tetrafluorophenyl]hydrobis(2,3,4,5,6-pentafluorophenyl)borate, [4-di-tert-butylphosphino-2,3,5,6-tetrafluorophenyl]hydrobis(2,3,4,5,6-pentafluorophenyl)borate; carboranes, (Λ,R)-(1,1′-binaphthalene-2,2′diolato)(bis(tetrachlor-1,2-benzenediolato)phosphate(V)) (BINPHAT), [Δ-tris(tetrachloro-1,2-benzenediolato)phosphate(V)] (TRISPHAT); fluoroantimonates, such as hexafluoroantimonate (SbF₆⁻); fluorophosphates, such as hexafluorophophosphate (PF₆⁻); fluoroborates, such as tetrafluoroborate (BF₄); derivatives thereof; and combinations thereof. As used herein, “derivatives” of the counterion refer to or include counterions or anions that resemble a base counterion, but that contain minor changes, variations, or substitutions, that do not substantially change the ability of the counterion to form a salt with the organic ion.

The organic photoactive component has a water contact angle of greater than or equal to about 65°, greater than or equal to about 70°, greater than or equal to about 80°, greater than or equal to about 90°, greater than or equal to about 95°, or greater than or equal to about 100°. Put another way, the active layer 16 comprising or consisting essentially of the photoactive component has the above water contact angle. Put yet another way, the active layer 16 comprising or consisting essentially of the photoactive component and the electron acceptor have the above water contact angle. Put yet another way still, the active layer 16 has the above water contact angle. Therefore, in various embodiments, the photoactive neutral organic molecule or the counterion of a photoactive organic salt is modified or tuned to include at least one hydrophobic moiety, which increases the water contact angle. The hydrophobic moiety, for example, can be covalently bonded to the neutral organic molecule or counterion. Non-limiting examples of suitable hydrophobic moieties include —CH₃, —SH, —Cl, —F, —CCl₃, PhCl₆, -PhCl₅, —CF₃, PhF₆, -PhF₅, -PhF_{X}Cl_{y} (X=1 to 5 and Y=5−X), -PhF_{X}H_{y} (X=1 to 5 and Y=5−X), -PhClₓH_{y} (X=1 to 5 and Y=5−X) and other fluorocarbons, fluorinated phenyl borates, polar hydrophobic groups, and non-hydrogen-bond-forming groups. Relatively less hydrophobic moieties that may be utilized under various conditions include —OH, —COOH, (Ph)-CH, and combinations thereof, wherein the —OH, —COOH, and (Ph-CH) are more wettable (hydrophilic) and/or hydrogen bonding prone relative to the remaining moieties. As described further below, organic photoactive components with high water contact angles, i.e., greater than or equal to about 65°, provide device lifetimes of greater than or equal to about 1 year. As known by a person having ordinary skill in the art, a “water contact angle” is an angle where a water-vapor interface meet a solid surface of the active layer 16.

In various embodiments, the photoactive neutral organic molecule and/or the photoactive organic salt has an absolute highest occupied molecular orbital (HOMO) energy of greater than or equal to about 5.0 eV to less than or equal to about 5.6 eV, such as a HOMO energy of about 5.0 eV, about 5.1 eV, about 5.2 eV, about 5.3 eV, about 5.4 eV, about 5.5 eV, or about 5.6 eV. This HOMO energy provides elevated voltages and prevents unintended reactions with reactive oxygen species. The HOMO energy can be tuned by adding functional groups to photoactive neutral organic molecules or to counterions of photoactive organic salts. Tuning can also be performed by blending two or more anions together. Methods of tuning HOMO energies are further described in U.S. patent application Ser. No. 15/791,949 to Lunt et al., filed on Oct. 24, 2017, which is incorporated herein by reference in its entirety.

As shown in FIG. 1A, the second electrode 18 is positioned or deposited on a surface of the active layer 16 as, for example, a thin film. The second electrode 18, is positioned or deposited on the surface of the active layer 16 by solution deposition, drop casting, spin-coating, doctor blading, vacuum deposition, plasma sputtering, or e-beam deposition, as non-limiting examples, with thicknesses that allow for active-layer films that are visibly transparent or visibly opaque. Therefore, the second electrode 18 is in contact with a surface of the active layer 16 that opposes a surface of the active layer that is in contact with the first electrode 14. The second electrode 18 can be composed of any material known in the art. Non-limiting examples of electrode materials include indium tin oxide (ITO), aluminum doped zinc oxide (AZO), zinc oxide, and gallium zinc oxide (GZO), ultra-thin metals, such as Ag, Au, and Al, graphene, graphene oxide, poly(3,4-ethylenedioxythiophene) polystyrene sulfonate (PEDOT:PSS), and combinations thereof. In various embodiments, the second electrode 18 has a thickness of from about 1 nm to about 500 nm, from about 1 nm to about 200 nm, from about 10 nm to about 200 nm, from about 15 nm to about 150 nm, or from about 500 nm or less. Notwithstanding it is understood that changing the thickness of the second electrode 18 may alter the visible transparency of the photovoltaic device via modulation of complex optical interference and absorption associated with the multiple layers 12, 14, 16 in the photovoltaic device 10.

With further regard to the first electrode 14 and the second electrode 18, at least one of the electrodes 14, 18 may be visibly transparent in embodiments where the device is visibly opaque. In embodiments where the device is visibly transparent, both the first electrode 14 and the second electrode 18 are visibly transparent with thicknesses tailored to optimize the visible transparency in the active layer 16.

Although not shown in FIG. 1A or 1B, in various embodiments the photovoltaic devices 10, 10′ further include additional active layers, such as electron donors and/or electron acceptors, passive layers, electrode layers, or combinations thereof. For example, additional active layers may include molybdenum oxide (MoO₃), bathocuproine (BCP), C₆₀, or ITO. Additional electrodes may be composed of layers of Ag, Au, Pt, Al, or Cu. Additional non-limiting examples of electron acceptors include of C₇₀, C₈₄, [6,6]-phenyl-C61-butyric acid methyl ester, TiO₂, metal oxides, perovskites, other organic salts, organic molecules, or polymers. Active layers can be composed of neat planar layers of donor-acceptor pairs, mixed layers of blended donor-acceptor pairs, or graded layers of blended donor-acceptor pairs. In various embodiments, the photovoltaic device 10, 10′ is integrated into a multijunction device architecture as a subcell, wherein the multijunction device is either visibly transparent or visibly opaque. As described above, the photovoltaic device 10, 10′ can be incorporated into a photovoltaic or a photodetector. In various embodiments, the device 10, 10′ is sealed or hermetically sealed to prevent exposure of the substrate 12; electrodes 14, 18; active layer 16; and any additional layers. For example, the device 10, 10′ can be disposed within a sealed or hermetically sealed glass or plastic encapsulation.

As described above, the lifetime of organic photovoltaic devices can be extended by increasing the water contact angle of the organic photoactive component. The water contact angle can be increased by increasing the hydrophobicity of the organic photoactive component. Accordingly, the current technology also provides a method of fabricating an organic photovoltaic device having a lifetime (T₈₀ or T₅₀) of greater than or equal to about 340 hours, greater than or equal to about 1 year, greater than or equal to about 2 years, greater than or equal to about 3 years, greater than or equal to about 4 years, greater than or equal to about 5 years, greater than or equal to about 6 years, greater than or equal to about 7 years, greater than or equal to about 8 years, greater than or equal to about 9 years, greater than or equal to about 10 years, greater than or equal to about 15 years, greater than or equal to about 20 years, greater than or equal to about 25 years, greater than or equal to about 30 years, or greater than or equal to about 50 years. Accordingly, the lifetime (T₈₀ or T₅₀) can be from greater than or equal to about 340 hours to about 50 years or more.

The method comprises selecting an organic photoactive component. The organic photoactive component can be any photoactive neutral molecule or photoactive organic salt described herein. The method also comprises measuring a water contact angle of the organic photoactive component and determining whether the organic photoactive component has an acceptable water contact angle of greater than or equal to about 65° greater than or equal to about 70°, greater than or equal to about 80°, greater than or equal to about 90°, greater than or equal to about 95°, or greater than or equal to about 100°. An acceptable water contact angle can be predetermined. Methods of measuring water contact angles are known in the art and include, for example, the static sessile drop method, the pendent drop method, and the dynamic sessile drop method.

In some embodiments the organic photoactive component has an acceptable water contact angle, for example, a predetermined water contact angle of about 65°. When the water contact angle is not acceptable, i.e., when the water contact angle is less than about 65°, the method comprises tuning the organic photoactive component until the organic photoactive component has a water contact angle that is acceptable. Tuning the organic photoactive component until the organic photoactive component has a water contact angle that is acceptable comprises binding hydrophobic moieties to the organic photoactive component, i.e., to either the photoactive neutral molecule or the counterion of the photoactive organic salt. As described above, non-limiting examples of suitable hydrophobic moieties include —CH₃, —SH, —Cl, —F, —CCl₃, PhCl₆, -PhCl₅, —CF₃, PhF₆, -PhF₆, -PhF_{X}Cl_{y} (X=1 to 5 and Y=5−X), -PhF_{X}H_{y} (X=1 to 5 and Y=5−X), -PhClₓH_{y} (X=1 to 5 and Y=5−X) and other fluorocarbons, polar hydrophobic groups, and non-hydrogen-bond-forming groups. Less hydrophobic moieties include —OH, —COOH, (Ph)-CH and combinations thereof, wherein the OH, COOH, and (Ph)—CH are more wettable (hydrophilic) and/or hydrogen bonding prone relative to the remaining moieties.

In various embodiments, the method also comprises tuning the photoactive neutral organic molecule or the photoactive organic salt to have a HOMO energy of greater than or equal to about 5.0 eV to less than or equal to about 5.6 eV, such as a HOMO energy of about 5.0 eV, about 5.1 eV, about 5.2 eV, about 5.3 eV, about 5.4 eV, about 5.5 eV, or about 5.6 eV as described above.

The method also comprises disposing the organic photoactive component having a water contact angle of greater than or equal to about 65° (or other predetermined acceptable water contact angle) into a photovoltaic device. Disposing the organic photoactive component having a water contact angle of greater than or equal to about 60° into a photovoltaic device into a photovoltaic device comprises disposing the organic photoactive component having a water contact angle of greater than or equal to about 65° onto a layer of a photovoltaic device. Accordingly, in some embodiments, the method also comprises disposing a first electrode onto a substrate and disposing the organic photoactive component having a water contact angle of greater than or equal to about 60° on the first electrode as an active layer. Additional layers, as discussed herein, can also be disposed onto the device.

In some embodiments, the method further comprises encapsulating and sealing the organic photovoltaic device in an environment comprising, consisting essentially of, or consisting essentially of nitrogen gas. By an environment “consisting essentially of nitrogen,” it is meant that a small amount (for example, less than or equal to about 10 vol. %) of unavoidable impurity gases, i.e., gases other than nitrogen, may be present within the environment. The encapsulating comprises encapsulating the photovoltaic device in in an encapsulation comprising, for example, glass, cavity glass, or a plastic, each of which may be visibly transparent. The sealing comprises sealing the edges of the encapsulation with an adhesive, such as an epoxy.

Embodiments of the present technology are further illustrated through the following non-limiting example.

### Example

Solar energy deployment can be augmented with the use of wavelength-selective transparent photovoltaics. Moving forward, operating lifetime is an important challenge that must be addressed to enable commercial viability of these emerging technologies. Here, the lifetimes of PVs with organic near-infrared selective small molecules and molecular salts are investigated and devices featuring organic salts with varied counterions are studied. Based on the tunability afforded by anion exchange, it is demonstrated that an extrapolated lifetime of 7±2 years from continuous illumination measurements on organic salt devices held at the maximum power point. These lifetimes are compared with changes in external quantum efficiency, hydrophobicity, molecular orbital levels, and optical absorption to determine the limiting characteristics and failure mechanisms of PV devices utilizing each donor. Surprisingly, a key correlation is shown between the lifetime and the hydrophobicity of the donor layer, providing a targeted parameter for designing organic molecules and salts with exceptional lifetime and commercial viability.

### Methods

Device Fabrication:

Molecular salts are synthesized as described in previous studies, such as by Suddard-Bangsund et al. (Adv. Energy Mater. 2015, 1501659), which is incorporated herein by reference in its entirety. Prior to device fabrication, glass substrates pre-patterned with 120 nm of indium tin oxide (ITO) (Xinyan Technology) are cleaned via sequential sonication in a mixture of soap and de-ionized (DI) water, pure DI water, and acetone for 5 minutes each. Substrates are then submerged in boiling isopropanol and exposed to oxygen plasma for 5 minutes each. 5 mm² devices are then deposited through a shadow mask in the following architecture: MoO₃ (Alfa Aesar) (10 nm)/Donor/Acceptor/bathocuproine (Luminescence Technology, Inc.) (BCP) (7.5 nm)/Ag (Kurt J. Lesker Co.) (80 nm). Salt device donor/acceptor layers consist essentially of CyX (y nm)/C₆₀ (MER Corp.) (40 nm), where X is the anion paired with the Cy⁺ cation and y is the donor layer thickness (12.5 nm for CyTPFB and CyTRIS, 25 nm for CyTFM, 7.5 nm for CyPF₆, and 15 nm for CyI). Donor/acceptor layers for other devices consist essentially of ClAlPc (TCl) (15 nm)/C60 (30 nm) (PHJs) or ClAlPc (11 nm)/ClAlPc:C60 (1:1 vol., 7.5 nm)/C60 (26 nm) (PMHJs). Salt layers are spin-coated in a nitrogen environment at 2000 RPM for 20 seconds from various concentrations in 3:1 vol. chlorobenzene:dichloromethane (CyTPFB) or neat chlorobenzene (other salts). All other layers are thermally deposited at 0.1 nm s⁻¹ in vacuum with a base pressure of <3×10⁻⁶ Torr. Device substrates are then edge-sealed using epoxy in nitrogen under cavity glass with an oxygen and moisture getter.

Lifetime Testing:

Prior to lifetime testing, current density (J) is measured as a function of voltage (V) under illumination by a Xe arc lamp to determine the highest performing devices on each substrate for lifetime testing. Illumination intensity is calibrated to 1 sun with a NREL-calibrated Si reference cell with KG5 filter. Substrates are then loaded into testing modules equipped with temperature sensors and photodetectors and are illuminated by a sulfur plasma lamp (Chameleon) with spectrum comparable to AM1.5 between 350-820 nm. The illumination intensity at each module position is calibrated to approximately 1 sun with a NREL-calibrated Si reference cell with KG5 filter. Module temperatures are approximately 60° C. under illumination. Customized electronics (Science Wares) are utilized to hold devices at maximum power point, measure illumination intensity and mismatch corrected J-V characteristics on each device once per hour, and continuously monitor temperature on each module. Selected devices are periodically removed from the lifetime testing apparatus for external quantum efficiency (EQE) measurements, which are calibrated by a Newport-calibrated Si detector under a quartz tungsten halogen lamp.

Quantitative Lifetime Estimation:

Lifetimes are defined as the time over which the power conversion efficiency (PCE) reached 80% or 50% of the initial value after any burn-in (T₈₀ or T₅₀ respectively). Lifetime tests are conducted either for 1000 hours or until all devices on a given substrate reached T₅₀. To calculate T₈₀ and T₅₀ under ambient conditions, 1-sun direct irradiance (1000 W/m²) is divided by the average global horizontal irradiance for Kansas City, Mo. (4.3 kWh/m²-day, approximately equal to the average for the United States) to calculate a time multiplier of 5.66. For devices that do not reach T₅₀ after 1000 hours of constant illumination, a linear regression is fit to normalized performance data following initial burn-in to extrapolate T₈₀ and T₅₀.

Surface and Optical Characterization:

Contact angles are measured with a KRÜSS DSA-100 drop shape analyzer for neat (flat) donor films that are deposited on glass. AFM data are measured in contact mode for films deposited on Si substrates. Transmission is measured with a UV/VIS spectrometer without a reference sample.

### Results and Discussion

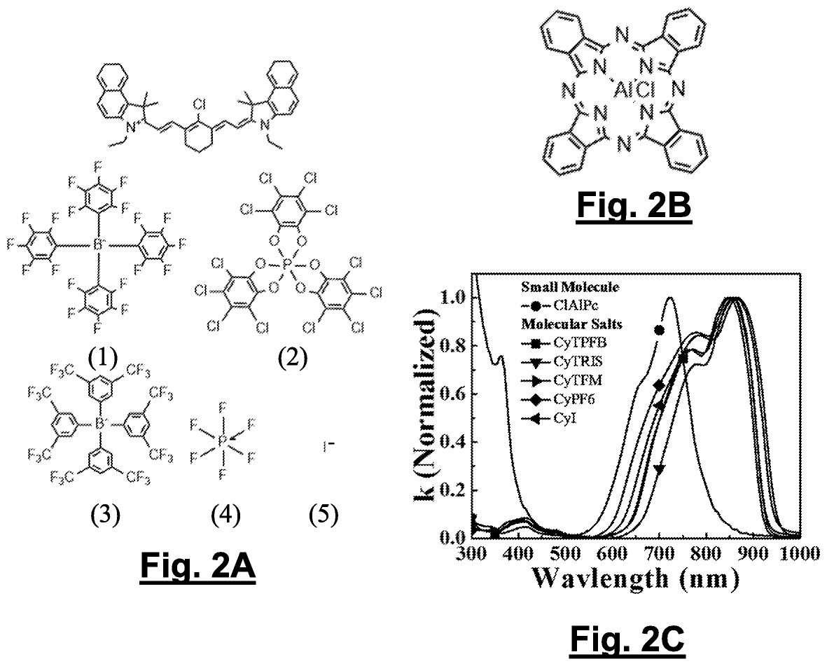

The operating lifetimes of OPV architectures are reported utilizing two classes of NIR-selective donors, solution-deposited molecular salts and vacuum-deposited small molecules, to determine the effects of donor molecular structure, morphology, molecular orbitals, and surface properties on device stability. For the molecular salts, a NIR selective heptamethine cation (Cy⁺) is paired with various anions including tetrakis(pentafluorophenyl)borate (CyTPFB), Δ-tris(tetrachloro-1,2-benzendiolato)phosphate(V) (CyTRIS), tetrakis[3,5-bis(trifluoromethyl)phenyl]borate (CyTFM), PF₆ (CyPF₆), and I (CyI). Cy⁺ and the various anions are illustrated in FIG. 2A. Cy salts are prepared by anion exchange of the parent CyI compound. Planar heterojunctions (PHJs) and planar-mixed heterojunctions (PMHJs) are investigated utilizing chloroaluminum phthalocyanine (ClAlPc), a NIR-selective vacuum-deposited small molecule, which has previously been shown in wavelength-selective HTPVs. The absorption spectra for all donors are shown in FIG. 2C.

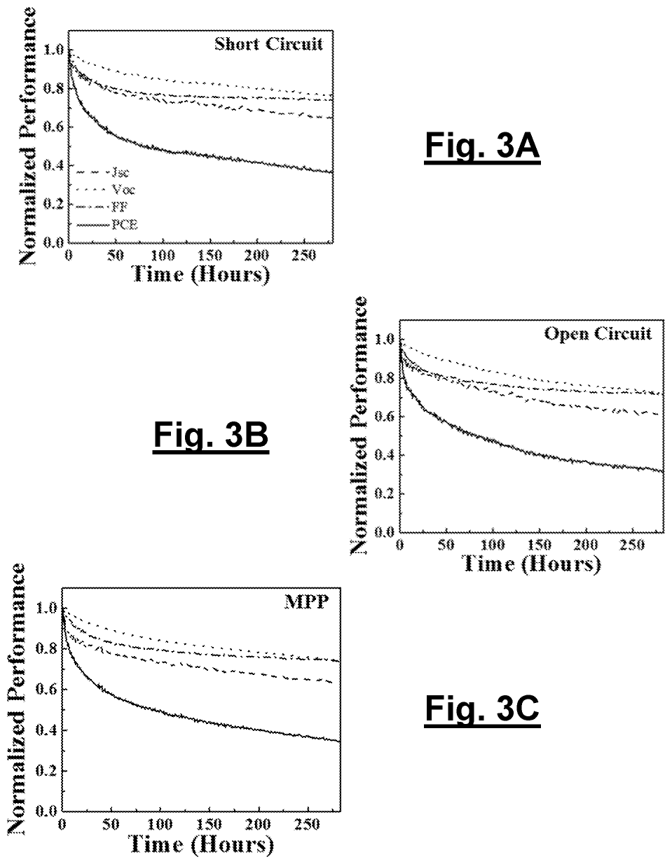

PHJ and PMHJ devices are fabricated and encapsulated under nitrogen. Four devices across at least two substrates per architecture are then tested under constant 1-sun illumination while being held at maximum power point (MPP) for 1000 hrs. MPP is focused on because it represents a realistic load placed on devices in practical applications. Moreover, surprisingly, significant differences are not observed in stability for the various architectures tested at short circuit, open circuit, and MPP as illustrated in FIGS. 3A-3C. Current-voltage characteristics are measured once per hour to extract time dependent performance parameters, resulting in only a brief pause in holding the cell at the MPP. External quantum efficiencies (EQEs) and transmission measurements are collected periodically on representative devices via brief removal from the lifetime tester. Lifetimes are typically defined as the time over which the power conversion efficiency (PCE) reaches 80% or 50% of the initial value following any burn-in (T₈₀ and T₅₀ respectively). Accelerated lifetime values are multiplied by 5.66×average hours of 1-sun illumination per day to convert from accelerated constant illumination to ambient conditions in Kansas City, Mo., which closely represents the average daily illumination in the United States (and peak power of ˜1000 W/m²). Greatly enhanced measured lifetimes from seasons to years in some cases for devices tested under constant illumination and outdoors respectively have been reported. This suggests that this extrapolation can be an accurate representation of lifetime under ambient illumination.

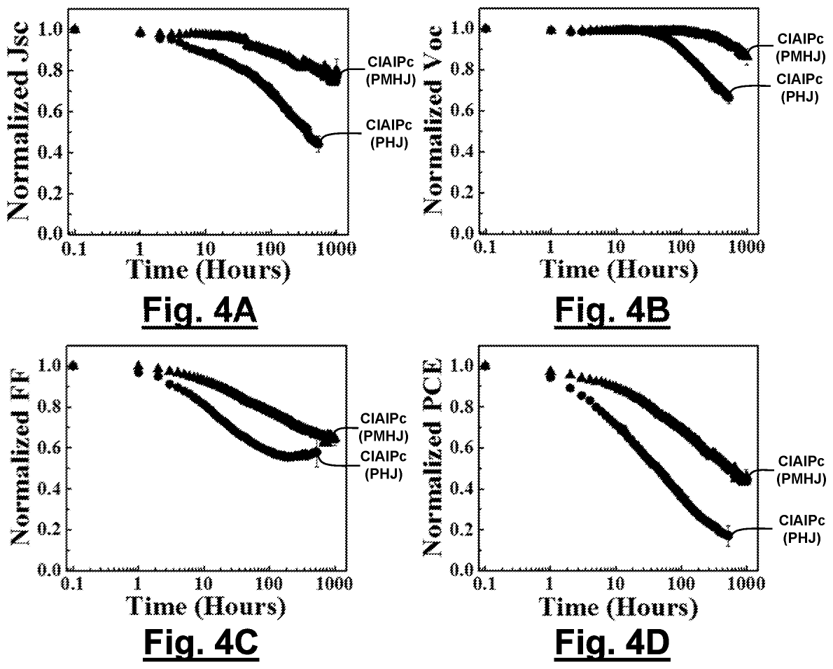

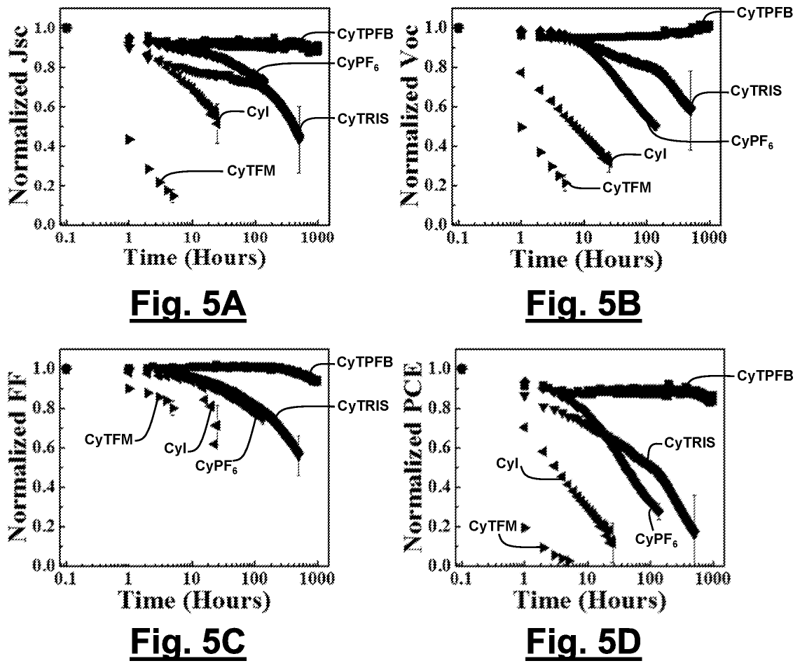

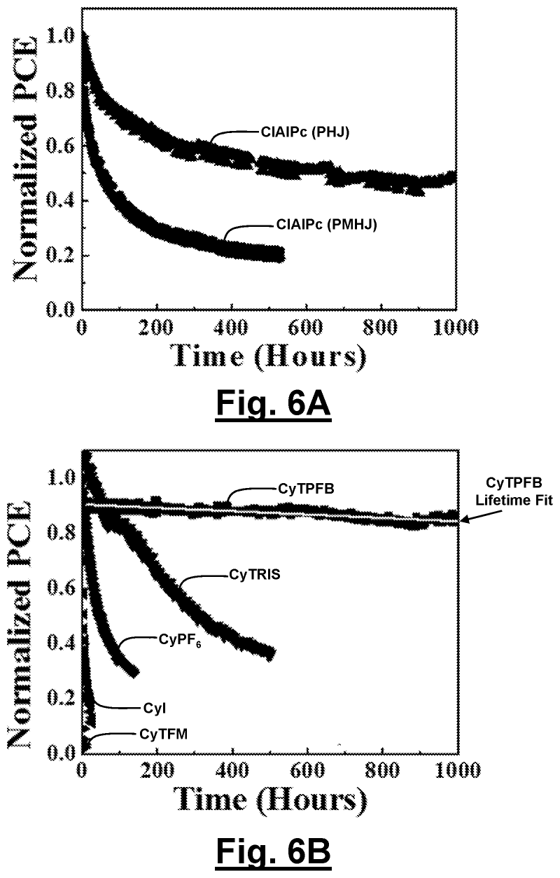

Normalized short circuit current density (J_{sc}), V_{oc}, fill factor (FF), and PCE characteristics are shown as a function of time in FIGS. 4A-4D for small molecule donors and in FIGS. 5A-5D for molecular salt donors. Representative best lifetime data are shown in FIGS. 6A-6B for all architectures. A wide range of device lifetimes among the architectures tested are shown. For example, the ClAlPc PMHJs exhibit significantly higher stability than the ClAlPc PHJs, with a champion T₅₀ of 4380 hours compared to 270 hours, respectively. In the ClAlPc architectures, J_{sc} and FF losses dominate the performance roll-off for approximately the first 30 hours of each test, after which V_{oc} begins to decline first in the PHJs and then in the PMHJs. Surprisingly, a larger range of lifetimes is observed throughout the organic salts even though they all contain the same photoactive cation. CyTPFB devices show dramatically enhanced stability compared to the ClAlPc devices, as well as the rest of the salt devices with the best T₅₀ of 7±2 years. Salt devices with other anions exhibit comparable lifetimes to the ClAlPc PHJs, with the exception of CyTRIS (T₅₀=1740 hours). CyPF₆ devices have a T₅₀ of 280 hours, while CyI devices exhibit a T₅₀ of 18 hours. CyTFM devices exhibit the lowest stabilities, with a best T₅₀ of only 4 hours, despite similar initial performance to CyTPFB. For the salt devices, J_{sc}, V_{oc}, and FF values simultaneously roll off within 100 hours and largely determine the overall losses in PCE, with the exception of CyTPFB. For CyTPFB devices, J_{sc} undergoes a slight burn-in over the first 10 hours of the tests before stabilizing, FF slightly rolls off after 200 hours, and V_{oc} remains essentially unchanged.

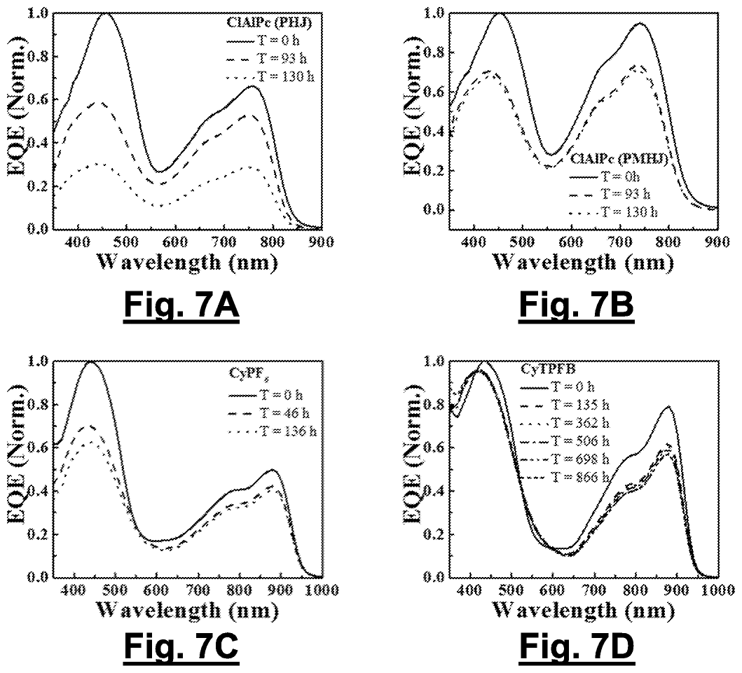

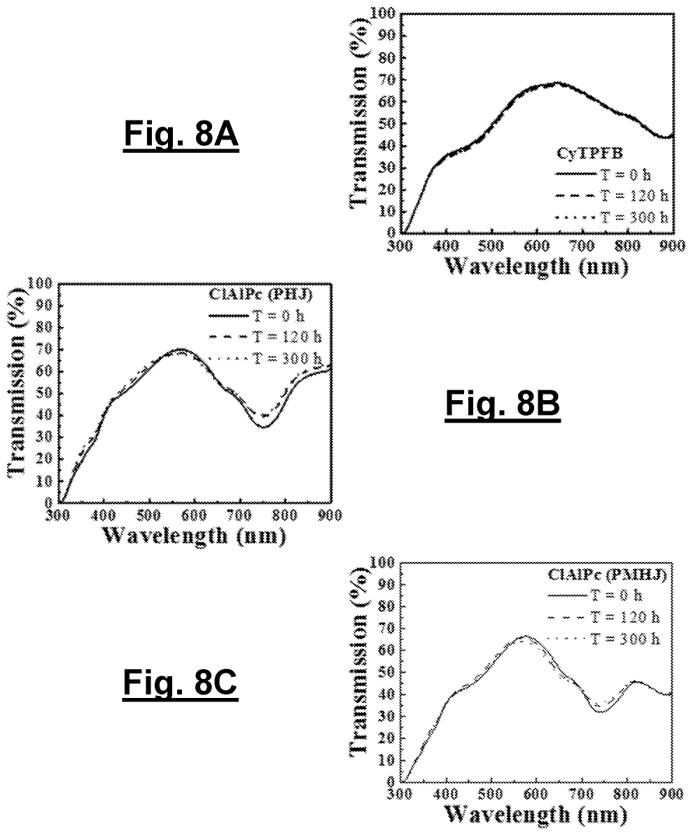

EQE data that is measured for individual devices from selected architectures during lifetime testing are shown in FIGS. 7A-7D, while optical transmission data are shown in FIGS. 8A-8C. While the ClAlPc PHJ EQE rolls off significantly as time approaches T₅₀, the EQEs for other architectures stabilize shortly after lifetime tests are started. The CyTPFB device experiences only a slight EQE roll-off of approximately 10%, correlating with the J_{sc} burn-in. Optical transmission is increased slightly over time around ClAlPc absorption wavelengths, indicating slight photobleaching, however all architectures retain apparent absorption well beyond NIR EQE losses that are observed. The losses in C₆₀ EQE suggest that the uniform losses in EQE likely indicate that these defects originate on the donor and act as recombination sites for all hole collection.

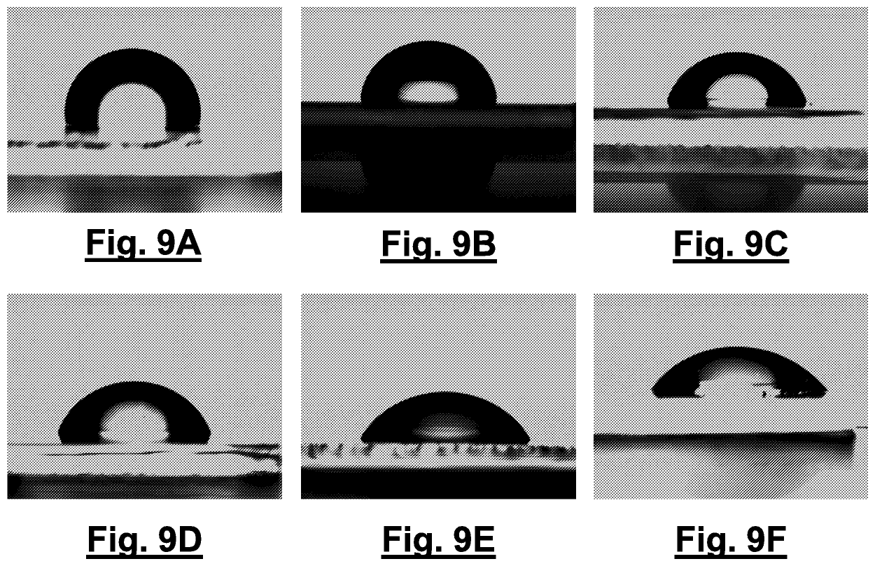

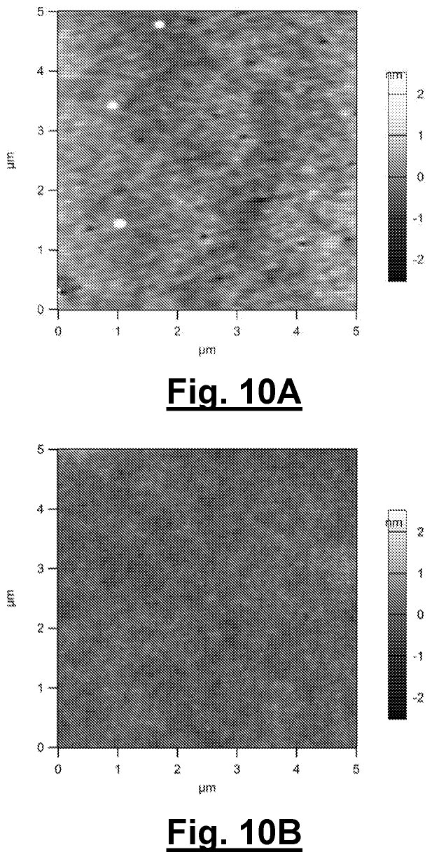

Physical properties including the HOMO and water contact angles for isolated donor and mixed ClAlPc:C₆₀ films are shown in Table 1 below. Representative photographs that are used to calculate water contact angles from selected films are shown in FIGS. 9A-9F. Co-depositing ClAlPc and C₆₀ together in a mixed layer increases the contact angle from 62±1° for neat ClAlPc to 69±2°. Interestingly, CyTPFB exhibits a contact angle of 99.8±0.4° (hydrophobic) while CyTFM has a contact angle of 58±4° (hydrophilic). CyTRIS, CyPF₆, and CyI exhibit contact angles of 80±1°, 75±4°, and 71±2° respectively. The salt films are amorphous, each exhibit RMS roughness <1 nm, and none exhibit any significant solubility in water. AFM data shown for CyTPFB and CyTFM in FIGS. 10A-10B demonstrate no significant change in surface roughness, indicating variation in hydrophobicity is due primarily to the chemical structure of the anion.

TABLE 1
Champion device lifetimes converted to ambient illumination and
water contact angles measured from 50 nm isolated donor films.

| | | | | | Water | |
|---|---|---|---|---|---|---|
| | | | | | Contact | |
| | | | | | Angle | HOMO |
| Donor | T₈₀ | | T₅₀ | | [Degrees] | (eV) |
| CyTPFB | 3 | years^{a)} | 7 | years^{a)} | 99.8 ± 0.4 | 5.45 |
| CyTRIS | 340 | hours | 1740 | hours | 80 ± 1 | 4.9 |
| CyPF₆ | 60 | hours | 280 | hours | 75 ± 4 | 4.8 |
| Cyl | 4 | hours | 18 | hours | 71 ± 2 | 4.6 |
| CyTFM | 1.4 | hours | 4 | hours | 58 ± 4 | 5.3 |
| CIAIPc (PHJ) | 30 | hours | 270 | hours | 62 ± 1 | 5.5 |
| CIAIPc (PMHJ) | 270 | hours | 4380 | hours | 69 ± 2 | 5.5 |

^{a)}Values calculated from linear extrapolation.

The deviation between ClAlPc PHJ and PMHJ stabilities is largely due to the morphology of the photoactive layers. In PMHJs, photocurrent generation is significantly enhanced and confirmed by increases in EQE. This enhancement primarily stems from a shorter length over which excitons need to diffuse before dissociation, resulting in an overall shorter exciton lifetime. Excitons in the PMHJ are therefore less likely to interact or annihilate with polarons or other excitons to form defects which act as charge traps in the bulk donor and acceptor layers. The longer exciton lifetimes in the PHJs increase the probability of these defect generating events, causing more immediate roll-offs in J_{sc} and FF. The losses in V_{oc} across both architectures can be attributed to the gradual formation of photo-activated interfacial states which also further degrade J_{sc}. Because the donor-acceptor interfacial area is considerably larger in the PMHJs than in the PHJs, longer periods of illumination may be required to form a significant concentration of interfacial states to affect the V_{oc}. As shown in bulk heterojunction architectures, PMHJ stabilities can potentially be further improved with the incorporation of additional donor and acceptor materials in the mixed layer to prevent phase separation.

The donor is the only unique material in each architecture. Changes in device stability are therefore unlikely to originate from electrode, transport, or acceptor layer degradation. Although all the devices are encapsulated in a nitrogen environment, oxygen and moisture can still be present in ppm quantities during encapsulation or leak through the seal and penetrate top electrodes to damage photoactive materials. Thus, one possible explanation for the large lifetime variation is the deepening of the donor HOMO level which could alter the generation efficiency of reactive oxygen species. Superoxides, which are formed in a charge transfer process if the HOMO is closer to the vacuum level than the oxygen ground state, can photobleach the donor material, severely limiting the lifetime of the collective device. Such a mechanism would be expected to degrade absorption with time. However, surprisingly, little correlation between HOMO and lifetime is shown in Table 1 and little reduction in the absorption efficiency in FIGS. 8A-8C. In particular, the key comparison between CyTPFB and CyTFM shows that while these two compounds have similar HOMO, similar voltage, and even similar fluorinated chemical structures, they have vastly different lifetimes. Though reactive oxygen species may still play a role in lifetime, this indicates the presence of a separate degradation mechanism.

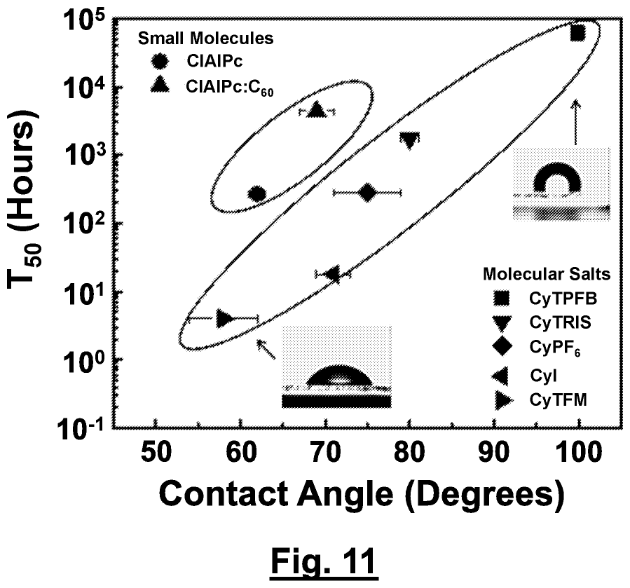

An alternative explanation could stem from the degree of hydrophobicity (as measured by water contact angle). Indeed, in FIG. 11, lifetime versus the water contact angle is plotted for the respective donor types. The salt lifetimes correlate exponentially (linearly on a semilog plot) to water contact angle, where contact angle increases from 58±4° for CyTFM to 99.8±0.4° for CyTPFB, while lifetime increases from 4 hours to 7±2 years respectively. Additionally, the order of magnitude difference in lifetime between the ClAlPc PHJ and PMHJ, while this is largely attributed to exciton lifetime reductions, is also seemingly correlated with the difference in contact angle which could imply additional degradation mechanisms similar to the salts that are reduced as the layer becomes more hydrophobic or is reflecting a variation in the morphology (surface roughness) that results in lowered exciton lifetime.

The most striking variation is the 40° difference in water contact angle between CyTPFB and CyTFM. This is explained by the degree of functionalization of the respective anions. Polar functional groups can significantly alter the solubility of the collective salt in a given solvent. The phenyl groups present on the TFM anion are made slightly more polar by the trifluoromethyl functionalization as compared to the more symmetric distribution of fluorine atoms around the phenyl groups on the TPFB anion. Although both CyTPFB and CyTFM exhibit low water solubilities, the structure of the TFM anion may still permit chemical interactions (particularly at the C—H bonds in the anion) with water resulting in a lower contact angle. The stark differences in lifetime are then likely explained by ppm or sub-ppm levels of moisture interaction still present even in packaged devices. Differences in hydrophobicity can potentially also represent prevention of other sources of degradation such as physical repulsion of reactive species (oxygen, hydroxyl, water, and nitrogen based radical species), limit hydrogen bonding interactions, or increase inertness to interaction at the C₆₀ interface where donor-acceptor (C₆₀) adducts form under favorable interactions. The hydrophobicities of buffer and encapsulation layers have been correlated to lifetime; however, lifetime has not been connected to the active layer hydrophobicity. The design of hydrophobic photoactive materials therefore provides a key metric to identify highly stable molecular salt and non-salt devices.

For compounds that have higher degree of water solubility, water contact angle could be made with dynamic wetting measurements or correlated to other representative solvent contact angles.

This demonstrates the impact of chemical structure and morphology of NIR wavelength-selective donor materials on the lifetime of OPV devices. A series of organic small molecules and molecular salts containing a common photoactive cation with varied counterion are also systematically investigated. Studying the range of donor materials in otherwise identical architectures shows that most changes in stability are intrinsically related to the donor material and not products of acceptor, transport, or electrode layer degradation. Further, the impact of HOMO, water contact angle, and anion structure in the case of the molecular salts is evaluated, and a clear correlation between stability and hydrophobicity is displayed. Devices utilizing a hydrophobic donor layer (CyTPFB) exhibit a champion lifetime (CyTPFB) of 7±2 years, demonstrating improvement in lifetime related specifically to active layer hydrophobicity. While the hydrophobicity may be an indicator of other interactions, it nonetheless serves as a rapid indicator/screening-metric for longer lifetimes, and allows for the fabrication of stable, NIR selective donor materials that can be utilized in opaque and visibly transparent PVs.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An organic photovoltaic device comprising:
an active layer comprising an organic photoactive component having a water contact angle of greater than or equal to about 65°.

2. The organic photovoltaic device according to claim 1, wherein the organic photoactive component comprises a neutral organic molecule.

3. The organic photovoltaic device according to claim 1, wherein the organic photoactive component comprises an organic salt comprising an ion and a counterion.

4. The organic photoactive device according to claim 3, wherein the counterion is fluorinated phenyl borate.

5. The organic photovoltaic device according to claim 3, wherein the counterion ion is tetrakis(pentafluorophenyl)borate and the organic photovoltaic device has a lifetime T₈₀ of greater than or equal to about 340 hours.

6. The organic photovoltaic device according to claim 3, wherein the organic salt comprises an absolute highest occupied molecular orbital energy of greater than 5.2 eV.

7. The organic photovoltaic device according to claim 1, wherein the organic photoactive component comprises at least one of a neutral cyanine and a cyanine salt.

8. The organic photovoltaic device according to claim 1, wherein the organic photoactive component has a water contact angle of greater than or equal to about 90°.

9. The organic photovoltaic device according to claim 1, wherein the organic photoactive component has a strongest peak absorbance of greater than or equal to about 675 nm.

10. The organic photovoltaic device according to claim 1, wherein the organic photovoltaic device is sealed within a glass or plastic encapsulation.

11. The organic photovoltaic device according to claim 1, wherein the organic photovoltaic device has a lifetime T₈₀ of greater than or equal to about 340 hours.

12. The organic photovoltaic device according to claim 1, wherein the active layer further comprises a fullerene electron acceptor or the device comprises a complementary layer that comprises a fullerene electron acceptor.

13. The organic photovoltaic device according to claim 1, wherein the active layer further comprises a non-fullerene electron acceptor or the device comprises a complementary layer that comprises a non-fullerene electron acceptor.

14. An organic photovoltaic device comprising:
an active layer disposed on a substrate,
wherein the active layer comprises an organic photoactive component having a water contact angle on the substrate of greater than or equal to about 65° and an absolute highest occupied molecular orbital (HOMO) energy of greater than or equal to about 5.0 eV to less than or equal to about 5.6 eV, and
wherein the organic photovoltaic device has a lifetime T₈₀ of greater than or equal to about 340 hours.

15. The organic photovoltaic device according to claim 14, wherein the organic photovoltaic device is visibly transparent.

16. A method of fabricating a photovoltaic device, the method comprising:
selecting an organic photoactive component;
measuring a water contact angle of the organic photoactive component;
determining whether the organic photoactive component has a water contact angle of greater than or equal to about 65°;
when the water contact angle is less than about 65%, tuning the organic photoactive component until the organic photoactive component has a water contact angle that is greater than or equal to about 65°; and
disposing the organic photoactive component having a water contact angle of greater than or equal to about 65° into a photovoltaic device,
wherein the photovoltaic device has a lifetime T₈₀ of greater than or equal to about 340 hours.

17. The method according to claim 16, wherein the organic photoactive component is at least one of a neutral organic molecule and an organic salt comprising an ion and a counterion.

18. The method according to claim 17, wherein the neutral organic molecule is selected from the group consisting essentially of a cyanine, a phthalocyanine, a porphyrin, a thiophene, a perylene, a polymer, derivatives thereof, and combinations thereof and the organic salt is selected from the group consisting essentially of a polymethine salt, a cyanine salt, derivatives thereof, and combinations thereof.

19. The method according to claim 17, wherein the tuning the organic photoactive component until the organic photoactive component has a water contact angle that is greater than or equal to about 65° comprises adding at least one hydrophobic moiety to the neutral organic molecule or to the counterion.

20. The method according to claim 19, wherein the at least one hydrophobic moiety is selected from the group consisting —CH₃, —SH, —Cl, —F, —CCl₃, PhCl₆, -PhCl₅, —CF₃, PhF₆, -PhF₅, -PhF_{X}Cl_{y} (X=1 to 5 and Y=5−X), -PhF_{X}H_{y} (X=1 to 5 and Y=5−X), -PhCl_{X}H_{y} (X=1 to 5 and Y=5−X), and combinations thereof.

21. The method according to claim 19, wherein the counterion is a fluorocarbon or a fluorinated phenyl borate.

22. The method according to claim 16, further comprising encapsulating and sealing the organic photovoltaic device in an environment comprising nitrogen gas.
